(19) United States
(12) Patent Application Publication
(10) Pub. No.: US 2010/0162956 A1
(43) Pub. Date: Jul. 1, 2010

(54) Substrate Processing Apparatus and Substrate Mount Table Used in the Apparatus

(76) Inventors: Seishi Murakami, Yamanashi-Ken (JP); Kei Ogose, Yamanashi-Ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/989,936

(22) PCT Filed: Aug. 4, 2006
(86) PCT No.: PCT/JP2006/315525

§ 371 Date: Feb. 4, 2008

(30) Foreign Application Priority Data
Aug. 5, 2005 (JP) 2005-227465

(51) Int. Cl. H01L 21/683; C23C 16/00; C23C 16/46; H01L 21/477

(52) U.S. Cl. 118/725; 257/E21.497

(57) ABSTRACT

Disclosed is a susceptor which achieves uniform temperature distribution of a wafer placed on the susceptor, and also disclosed is a substrate processing apparatus provided with the susceptor. An annular recess 12a is formed in an intermediate portion between the central portion and the peripheral portion of a wafer support surface of the susceptor 12. Due to the provision of the recess, the substrate heating effect by thermal radiation from the susceptor is suppressed in the intermediate portion. The geometrical dimension of the recess is determined taking the chamber internal pressure into consideration.

### TECHNICAL FIELD

The present invention relates to a substrate processing apparatus that performs a heat treatment to a substrate such as a wafer or a predetermined treatment such as CVD while heating a substrate, and also relates to a substrate mount table used in the substrate processing apparatus.

### BACKGROUND ART

In semiconductor device manufacturing processes, various kinds of gas processes, such as film forming processes and etching processes, are performed to a semiconductor wafer (hereinafter referred to simply as “wafer”) which is a substrate to be processed. In a CVD film deposition process of Ti, TiN or W among those processes, a wafer is heated up to, for example, about 500 to 700° C. by a resistance heater or a lamp heater while the wafer is placed on a susceptor formed of a ceramic or a metal.

At this time, in view of uniformity of the process, in-plane uniformity of the wafer temperature distribution is necessary. To this end, uniformization of the susceptor temperature is considered. However, in a conventional susceptor, since the heat-dissipating amount at the peripheral portion is larger, the peripheral portion of the wafer support surface of the susceptor is likely to be relatively low. In addition, an amount of thermal radiation which is reflected by a shower head facing the susceptor and falls on the wafer is relatively larger in the center portion of the susceptor. As a result, the temperature of the wafer is higher in its center portion, and in-plane uniformity of the wafer temperature distribution can not be achieved.

For these reasons, in order to achieve in-plane uniformity of the wafer temperature distribution, heat input to the center portion and the peripheral portion of the susceptor should be intentionally differentiated. There has been known a technique for achieving the above which divides a susceptor into a plurality of heating zones, provides the heating zones with resistance heaters, respectively, and controls the power of each heater individually. However, in a case where the susceptor is made of a ceramic, if the temperature difference between the center portion and the peripheral portion is too large, it is possible that the susceptor is cracked or broken due to thermal stress. Accordingly, only by the aforementioned technique, it is difficult to achieve in-plane uniformity of the wafer temperature distribution. FIG. 21 shows the result of the temperature measurement in a wafer plane while the wafer was heated by using a conventional susceptor. As can be seen from the data plotted with a square in FIG. 21, the temperature in the center portion tends to be higher than the peripheral portion.

In order to solve the problem, there has been proposed a susceptor whose upper surface is provided with a recess, whose depth is largest at the center of the susceptor and becomes smaller as the measuring point goes from the center to the peripheral portion (See JP2004-52098A, for example).

In general, in-chamber component parts such as a susceptor is subjected to precoating before a film deposition process is performed, in order to prevent a wafer from being contaminated with metallic elements constituting the component parts. The precoating of the susceptor is performed without placing a wafer on the susceptor, whereby precoating films are formed on the whole surfaces of the susceptor including the wafer placing area. Thus, thermal radiation from the whole suscepter surfaces is suppressed.

In general, a susceptor is connected to the chamber bottom through a support member connected to the bottom center of the susceptor. Heat transfer through the support member draws heat from the susceptor. The amount of the heat transfer is not changed regardless of whether or not the precoating film exists. As a result of the fact that the thermal radiation from the whole surface of the susceptor is suppressed by the formation of the precoating film, influence of the heat transfer through the support member on the susceptor temperature distribution becomes larger. Thus, the temperature of the center portion of the susceptor, which is a portion near the susceptor, greatly lowers as compared with other portions, causing non-uniformity of the wafer in-plane temperature distribution.

In order to solve the above problem, it is considered that the calorific power of the heater assigned to heat the center portion of the susceptor is set to be higher than the calorific power of the heater assigned to heat the peripheral portion. In this case, however, the temperature of areas between the center portion and the peripheral portion of the susceptor, which is heat-insulated by the precoating and is little affected by the heat transfer through the support member, becomes higher as can be seen from the data plotted with black circles in FIG. 21. Thus, a sufficient level of in-plane temperature uniformity can not be achieved.

### DISCLOSURE OF THE INVENTION

Accordingly, the object of the present invention is to provide a substrate mount table that can achieve in-plane temperature uniformity of a wafer even if a precoating is applied to the substrate mount table for supporting a wafer, and also to provide a substrate processing apparatus provided with the substrate mount table.

In order to achieve the above objective, according to the first aspect of the present invention, there is provided a substrate processing apparatus that performs a heat treatment to a substrate, or performs a treatment while heating a substrate, the apparatus including: a chamber; an evacuating means that decreases pressure in the chamber; a substrate mount table that supports the substrate in the chamber; and a heating means that heats the substrate via the substrate mount table, wherein the substrate mount table has a first support surface formed in a center portion of the substrate mount table to support the substrate, a second support surface formed in a peripheral portion of the substrate mount table to support the substrate, and a recess formed between the first support surface and the second support surface, so that a gap is formed between the substrate placed on the substrate mount table and a bottom surface of the recess.

Further, according to the second aspect of the present invention, there is provided a substrate mount table that supports a substrate in a chamber, and is heated by a heating means to heat the substrate by heat of the substrate mount table, wherein the substrate mount table has a first support surface formed in a center portion of the substrate mount table to support the substrate, a first support surface formed in a peripheral portion of the substrate mount table to support the substrate, and a recess formed between the first support surface and the second support surface, so that a gap is formed between the substrate placed on the substrate mount table and a bottom surface of the recess.

As previously mentioned, when a precoating film is formed, the temperature of the intermediate area between the center portion and the peripheral portion of the substrate mount table becomes higher than the center portion and the peripheral portion of the substrate mount table. If the recess is formed in the intermediate area, the gap (distance) between the substrate mount table and the substrate in the intermediate area becomes larger. Thereby, the substrate heating effect of the substrate mount table in the intermediate area is suppressed. Thus, the temperature of the intermediate area of the substrate between the center portion and the peripheral portion of the substrate is lowered, uniformizing in-plane temperature distribution of the substrate.

When a substrate is placed on the substrate mount table, very small gaps exist between the substrate and the substrate mount table, in microscopic view. Under such a situation, the substrate is heated by thermal radiation from the substrate mount table and heat transfer mediated by gas molecules. The gas molecule-mediated heat transfer is greatly affected by the chamber internal pressure. The heat transmitting effect of the gas molecules also varies depending on the gas pressure (partial pressure). Thus, it is preferable to determine the geometrical dimension (shape, gap depth and its distribution) taking the gas pressure (partial pressure) during the process into consideration. Thereby, the need for complicated heating control of the substrate mount table is greatly reduced. That is, the need for intentional nonuniform heating of the substrate mount table is eliminated or is greatly reduced.

The size of the gap may be varied with location. Alternatively, the bottom surface of the recess may have a step.

In one preferred embodiment, the bottom surface of the recess has a plurality of annular areas which are arranged concentrically, and adjacent annular areas have different heights (depths).

In a typical embodiment, the substrate mount table is supported by a support member connected to a center portion of the substrate mount table. Preferably, the region where the first support surface is provided substantially corresponds to a region where the support member is provided.

In a typical embodiment, the heating means includes a resistance heater embedded in the substrate mount table. A plurality of heaters may be used as the heating means, and power supply to those heaters is preferably controlled independently. In one preferred embodiment, the heating means includes a first heater disposed in a center portion of the substrate mount table and a second heater disposed to surround the first heater. Power supply to those heaters is preferably controlled independently.

### BRIEF DESCRIPTION OF THE DRAWINGS

FIG. 1 is a cross sectional view of a film forming apparatus in one embodiment of the present invention.

FIG. 2 is an enlarged cross sectional view of a susceptor in the first embodiment used in the film forming apparatus of FIG. 1.

FIG. 3 is a cross sectional view of a susceptor in the second embodiment.

FIG. 4 is a cross sectional view of a susceptor in the third embodiment.

FIG. 5 is a cross sectional view of a susceptor in the fourth embodiment.

FIG. 6 is a cross sectional view of a susceptor in the fifth embodiment.

FIG. 7 is a cross sectional view of a susceptor in the sixth embodiment.

FIG. 8 is a cross sectional view showing the structure of a support member.

FIG. 9 is a horizontal cross sectional view showing the arrangement of heaters in a susceptor.

FIG. 10 shows drawings showing conditions of the susceptors in experiments, where (a) shows a non-precoated condition, (b) shows a precoated condition, and (c) shows a precoated condition of a susceptor provided with a recess.

FIG. 11 is a graph showing the measurement result of the wafer in-plane temperature distribution.

FIG. 12 is a graph showing the relationship between the gap-related temperature-lowering rate and the chamber internal pressure (with precoating).

FIG. 13 is a graph showing the relationship between the gap-related temperature-lowering rate and the chamber internal pressure (without precoating).

FIG. 14 is a graph showing the relationship between the gap-related temperature-lowering rate and the heater set temperature (with precoating).

FIG. 15 is a graph showing the relationship between the gap-related temperature-lowering rate and the heater set temperature (without precoating).

FIG. 16 is a flowchart showing the recess forming process of a susceptor.

FIG. 17 is a top plan view showing the structure of a susceptor in which recesses are formed.

FIG. 18 is a cross sectional view showing the structure of the susceptor in which the recesses are formed.

FIG. 19 is a graph showing the temperature distribution of a wafer placed on a susceptor with a recess and without recess.

FIG. 20 is a graph showing the temperature distribution of a wafer placed on the susceptor with a recess and without recess.

FIG. 21 is a graph showing the result of measurement of in-plane temperature distribution of a wafer in a case where a conventional susceptor is used.

### BEST MODE FOR CARRYING OUT THE INVENTION

Preferred embodiments of the present invention will be described below with reference to the drawings.

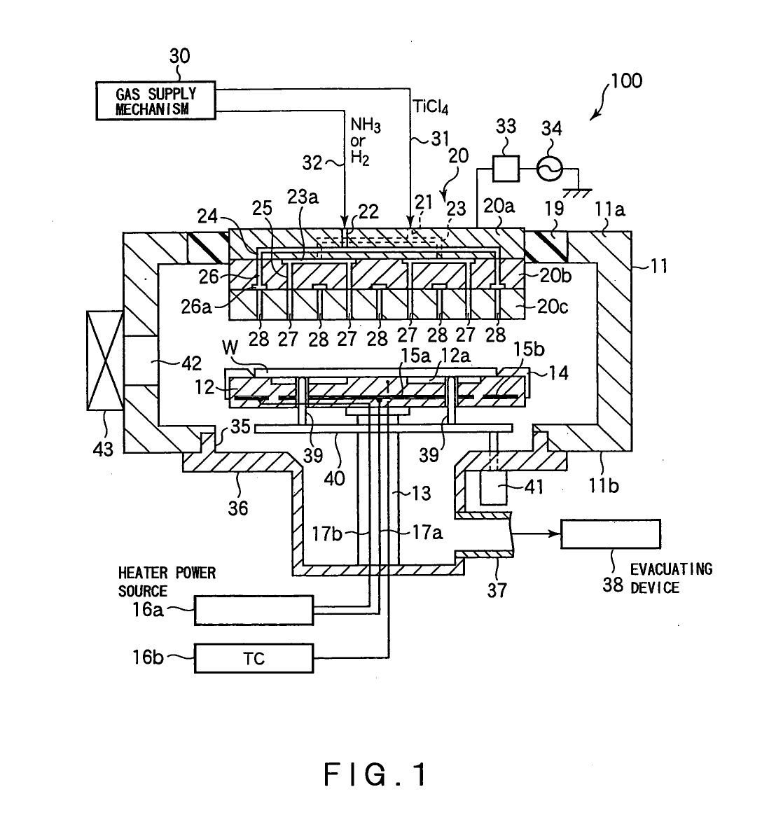

FIG. 1 is a cross sectional view of a film forming apparatus in a first embodiment of the present invention. The film forming apparatus 100 is for forming a TiN film or a Ti film, and includes a substantially cylindrical chamber 11. In the chamber 11, a discoid susceptor 12 for horizontally supporting a wafer W, which is a substrate to be processed, is supported by a cylindrical support member 13 that is disposed on a center bottom of the susceptor 12. The susceptor 12 is made of a ceramic such as Al₂O₃ and AlN. Herein, AlN is used. As described in detail below, a recess 12a is formed in a wafer support surface of the susceptor 12 at a position outside the center portion of the wafer support surface. A guide ring 14 for guiding a wafer W is disposed on an outer peripheral portion of the susceptor 12.

A heater 15a and a heater 15b as a heating means are embedded in the susceptor 12. The heater 15a is formed as a resistance heater for mainly heating a center portion of the susceptor 12, and is electrically connected to a heater power source 16a through a feed line 17a. Meanwhile, the heater 15b is formed as a resistance heater for mainly heating a peripheral portion of the susceptor 12, and is electrically connected to the heater power source 16a through a feed line 17b. The heaters 15a and 15b are formed as coiled heaters or pattern heaters, for example. Power is independently supplied to these heaters 15a and 15b to control a heating temperature, whereby a wafer W as a substrate to be processed is heated up to a predetermined temperature.

In addition, the susceptor 12 is equipped with a thermocouple 16b that detects the temperature of the susceptor 12 and feedbacks it to the heater power source 16a, so as to perform temperature control.

Although not shown, an electrode made of a metal such as W and Mo, or an alloy is embedded in a part near the surface of the susceptor 12. The electrode is used to maintain stability of a plasma during a plasma treatment. By connecting a radiofrequency power source to the electrode to apply thereto a radiofrequency bias of a predetermined frequency, film-forming molecules can be drawn into a wafer W to effectively form a film in a hole.

A showerhead 20 is disposed on a top wall 11a of the chamber 11 via an insulating member 19. The showerhead 20 is composed of an upper block body 20a, an intermediate block body 20b, and a lower block body 20c. The lower block body 20c has alternately arranged discharge holes 27 and 28 for discharging a gas. A first gas inlet port 21 and a second gas inlet port 22 are formed in the upper surface of the upper block body 20a. In the upper block body 20a, a number of gas passages 23 are diverged from the first gas inlet port 21. Gas passages 25 are formed in the intermediate block body 20b. The gas passages 23 are communicated with the gas passages 25 through communication passages 23a which are horizontally extended. Further, the gas passages 25 are communicated with the discharge holes 27 in the lower block body 20c. Meanwhile, in the upper block body 20a, a number of gas passages 24 are diverged from the second gas inlet port 22. Formed in the intermediate block body 20b are gas passages 26 with which the gas passages 24 are communicated. Further, the gas passages 26 are communicated with communication passages 26a which are horizontally extended in the intermediate block body 20b. The communication passages 26a are communicated with the number of discharge holes 28 in the lower block body 20c. The first and second gas inlet ports 21 and 22 are connected to gas lines 31 and 32, respectively.

Although not shown, a gas supply mechanism 30 is provided with: gas supply sources for a film deposition gas, a carrier gas, and a cleaning gas; gas pipings, and a massflow controller. During a process, TiCl₄ gas as a Ti-containing gas together with a carrier gas such as N₂ gas, is supplied to the showerhead 20 through the gas line 31 and the gas inlet port 21. A reduction gas which is NH₃ gas (when a TiN film is formed) or Hz gas (when a Ti film is formed), together with a dilution gas such as N₂ gas, is supplied to the showerhead 20 through the gas line 32 and the gas inlet port 22. The TiCl₄ gas, which has been introduced from the gas inlet port 21 into the showerhead 20, passes through the gas passages 23 and 25, and is discharged from the discharge holes 27 into the chamber 11. On the other hand, the NH₃ gas or the H₂ gas, which has been introduced from the gas inlet port 22 into the showerhead 20, passes through the gas passages 24 and 26, and is discharged from the discharge holes 28 into the chamber 11. Namely, the showerhead 20 is of a post-mix type in which TiCl₄ gas and NH₃ gas or H₂ gas as a reduction gas are totally, independently supplied into the chamber 11. After discharged into the chamber 11, the gases are mixed after discharge thereof to generate a reaction. However, the showerhead 20 may be of a pre-mix type. When the chamber 11 is cleaned, ClF₃ gas, for example, is supplied as a cleaning gas from the gas supply mechanism 30 into the chamber 11 through the gas line 31 and the showerhead 20.

A radiofrequency power source 34 is connected to the showerhead 20 via a matching device 33. A radiofrequency power of a predetermined frequency is adapted to be supplied from the radiofrequency power source 34 to the showerhead 20 according to need. When a Ti film is formed, a plasma CVD film forming process is possible by supplying a radiofrequency power from the radiofrequency power source 34 to make plasma a gas that has been supplied into the chamber 11 via the showerhead 20, in order to promote reactivity of a film forming reaction between TiCl₄ and H₂.

A circular opening 35 is formed in a center portion of a bottom wall 11b of the chamber 11. The bottom wall 11b is equipped with a recessed evacuating chamber 36 projecting downward to cover the opening 35. Connected to a side surface of the evacuating chamber 36 is an evacuating pipe 37 to which an evacuating device 38 is connected. By operating the evacuating device 38, pressure in the chamber 11 can be reduced to a predetermined vacuum degree.

The suscepter 12 includes three wafer support pins 39 (two wafer support pins 39 are illustrated) for supporting and vertically moving a wafer W, such that the wafer support pins 39 can be projected from the surface of the suscepter 12 and can be retracted therefrom. These wafer support pins 39 are fixed on a support plate 40, and are vertically moved by a driving mechanism 41, such as an air cylinder actuator, through the support plate 40.

Disposed in the sidewall of the chamber 11 are a loading/unloading port 42, and a gate valve 43 for opening and closing the loading/unloading port 42. A wafer W is transferred through the loading/unloading port 42 between the chamber 11 and a transfer chamber, not shown, adjacent to the chamber 11.

An annular recess 12a is formed in a periphery of the center portion of the wafer support surface of the susceptor 12. By forming the recess 12a in the wafer support surface of the susceptor 12, a condition can be realized in which a temperature difference between the center portion, the peripheral portion, and the intermediate area (area in which the recess is formed) of the wafer W can be reduced. Thus, the temperature of the wafer W can be uniformized.

Namely, since the thus formed recess 12a suppresses heat transfer from the susceptor 12, the temperature of the intermediate area of the wafer W (the area between the central portion and the peripheral portion of the wafer W), in which the temperature is likely to be raised, can be lowered, as compared with a case in which no recess 12a is formed. Thus, the provision of the recess 12a achieves in-plane uniformity of the temperature distribution of the wafer W. In this case, heating effect of the wafer W by heat transfer from the susceptor 12 changes depending on a distance (gap) between the susceptor 12 and the wafer W. Thus, the shape, the size and the depth (i.e., gap) of the recess 12a may be set such that a space allowing in-plane temperature uniformity of the wafer W placed on the susceptor 12 may be formed between the wafer W and the susceptor 12. Preferably, the gap is set to be not more than 1 mm, e.g., within a range between 0.01 mm to 1 mm.

In the recess 12a, a space is formed between the wafer W placed on the susceptor 12 and the susceptor 12, the space allowing the uniform in-plane temperature distribution of the wafer W supported by the susceptor 12 in accordance with the pressure in the chamber 11. The pressure in the space and the pressure in the chamber 11 are substantially the same.

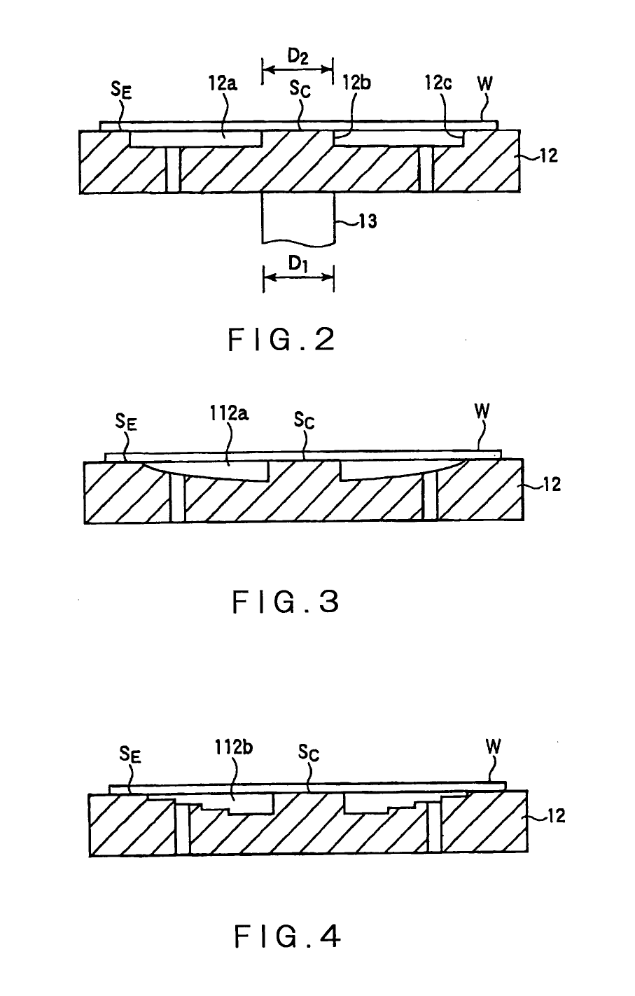

As shown in FIG. 2, for example, the recess 12a is formed, as a groove having a uniform depth, between a center projection 12b provided on the center portion of the susceptor 12, and a peripheral projection 12c provided on the peripheral portion of the susceptor 12. Thus, a first support surface S_{C} for supporting the center portion of a wafer W is formed on a top part of the center projection 12b, and a second support surface S_{E} for supporting the peripheral portion of the wafer W is formed on a top part of the peripheral projection 12c. The recess 12a functions to adjust heat transfer from the susceptor 12 to the wafer W so as to achieve in-plane temperature uniformity of the wafer W. By annularly forming the recess 12a to surround the center portion of the susceptor 12, heat transfer from the center projection 12b, which is inside the recess 12a, to the center portion of the wafer W can be maintained. When a precoating film is formed, influence of heat release to the support member 13 becomes marked to lower a temperature of the center portion of the susceptor 12, and thus the temperature of the center portion of the wafer W is lowered in accordance therewith. However, by forming the recess 12a to suppress heat transfer from this part to the wafer W, the temperature of the intermediate area of the wafer W between the center portion and the peripheral portion thereof is lowered to thereby achieve substantially uniform wafer in-plane temperature.

It is preferable to form the recess 12a such that the diameter D₂ of the center projection 12b is substantially the same as the diameter D₁ of the support member 13, or that the diameter D₂ is slightly larger than the diameter D₁. That is, an inner peripheral end of the recess 12a is preferably positioned right above the outer periphery of the support member 13, or slightly outside thereof. Since the center projection 12b is a part where drawing of heat therefrom is promoted by the support member 13 supporting the lower surface of the susceptor 12, it is preferable that the area of the center projection 12b substantially corresponds to the cross-sectional area of the support member 13. It is also preferable that the area of the recess 12a is determined in accordance with the cross-sectional area of the support member 13. For example, it is preferable to reduce the cross-sectional area of the support member 13 to reduce drawing of heat, whereby the area in which the recess 12a is formed can be reduced.

When the heaters are arranged in two zones, i.e., an inside zone and an outside zone, the recess 12a is formed in an area where the temperature of the susceptor 12 is most likely to rise. Namely, the recess 12a may be formed to overlap with the inside heater 15a. Alternatively, the recess 12a may be formed to overlap with an area between the heater 15a and the heater 15b.

Although depending on the diameter of the susceptor 12, an outer periphery, i.e., a boundary between the recess 12a and the peripheral projection 12c (inner periphery of the peripheral projection 12c) is preferably set to be positioned inside the outer circumference of the wafer W by 1 mm to 30 mm.

As long as desired in-plane temperature uniformity of the wafer W can be obtained, the shape of the recess (groove) is not limited to the embodiment (recess 12a) shown in FIG. 2. For example, as shown in FIG. 3, a recess 112a is possible whose depth is gradually reduced from the center side of the susceptor 12 toward the peripheral side thereof to form a curvature shape (for example, like a mortar). Alternatively, as shown in FIG. 4, for example, a recess 112b is possible whose depth is reduced stepwise in cross section from the center side of the susceptor 12 toward the peripheral side thereof.

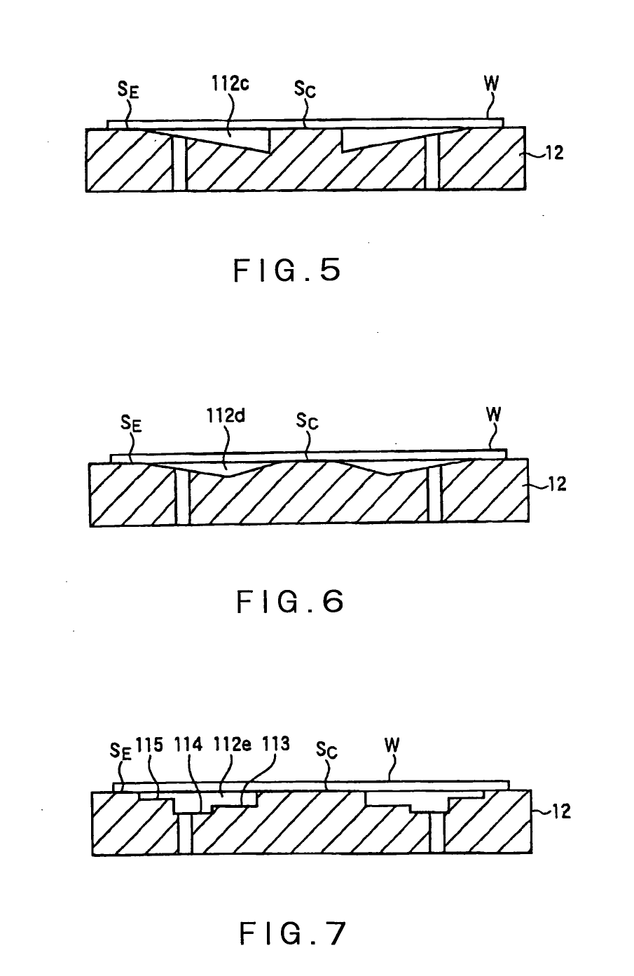

As shown in FIG. 5, for example, a recess 112c is possible whose depth is linearly reduced from the center side of the susceptor 12 toward the peripheral side thereof. Further, as shown in FIG. 6, for example, a recess 112d is possible whose depth is once increased from the center side of the susceptor 12 toward the peripheral part thereof, and is then gradually reduced toward the peripheral side to form a V-shape in cross section.

Furthermore, the bottom surface of the recess may have an annular vertical interval (step). As shown in FIG. 7, for example, it is possible to provide a recess 112e having a first bottom portion 113, a second bottom portion 114, and a third bottom portion 115, in this order from the center side of the susceptor 12 to the peripheral side thereof. In this case, in the recess 112e, the third bottom portion 115 is smallest in depth, the second bottom portion 114 is greatest in depth, and the first bottom portion 113 is intermediate between the second bottom portion 114 and the third bottom portion 115 in depth. The depths of the respective bottom portions can be determined by heating a wafer W with the use of the flat susceptor 12 and measuring temperature distribution of the wafer W. Namely, in an area of the susceptor 12 corresponding to a high-temperature part of the wafer W, the depth of the recess is set large to increase the gap, while in an area of the susceptor 12 corresponding to a low-temperature part of the wafer W, the depth of the recess is set small to reduce the gap.

In FIGS. 2 to 7, the depths of the respective recesses are emphatically illustrated. In the recesses 12a, 112a, 112b, 112c, 112d, and 112e which are taken by way of example, it is preferable that corners of the respective recesses are rounded (chamfered).

The depth of the recess 12a (112a, 112b, 112c, 112d) and an amount of heat transfer to a wafer W are correlated with each other. In addition, the higher the chamber internal pressure is, the higher the efficiency of heat transfer mediated by gas molecules is. Thus, heat is more easily transferred to a wafer W even when the depth of the recess 12a is unchanged. Accordingly, by grasping beforehand the relation between the depth of the recess 12a (i.e., height of the space) and an amount of heat transfer under various gas pressures in the chamber, it is possible to select the depth or the shape of the recess 12a which is most suitable for the process.

In addition to the provision of the recess 12a to the susceptor 12, as shown in FIG. 1, for example, the inside heater 15a and the outside heater 15b may be separately arranged, and power supply to the heaters 15a and 15b may be separately controlled so as to finely adjust temperature distribution. In this case, temperature control can be more accurately performed, while preventing the susceptor 12 from being cracked and/or broken. It is not necessary that two heaters are separately arranged as shown in FIG. 1, and a single heater is possible. However, with respect to a wafer W of a large diameter, such as 300 mm or more, it is difficult to maintain in-plane temperature uniformity, regardless of whether the number of the heater(s) is one or more than one. Further, adjustment of the heater pattern of a susceptor and adjustment of the winding number of coil are difficult, which makes difficult fine adjustment of heat uniformity of the susceptor (ceramic heater). Thus, it is particularly effective to control the in-plane temperature of the wafer W by forming the recess 12a as in the present invention.

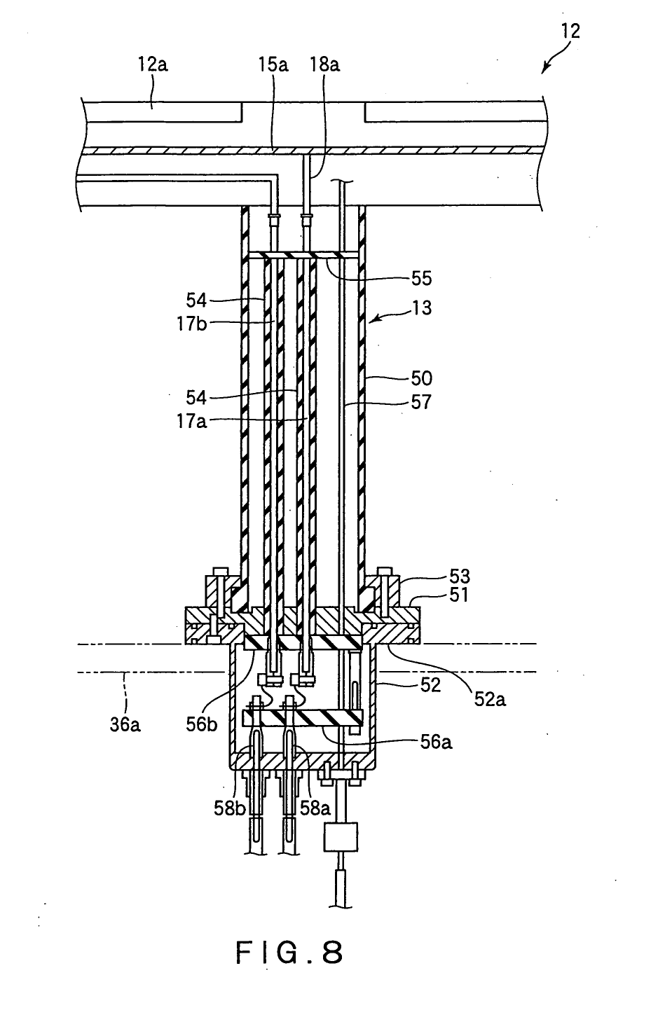

FIG. 8 is a cross sectional view showing the main part of the inner structure of the support member 13. The support member 13 mainly includes: a substantially cylindrical support body 50 for supporting the susceptor 12; a mounting plate 51 disposed on the lower part of the support body 50, the mounting plate 51 being made of nickel, aluminum, stainless steel, or the like; and a terminal box 52 mounted on the mounting plate 51.

The mounting plate 51 and the terminal box 52 made of aluminum or the like are secured to each other by screw cramping, for example. The mounting plate 51 is fixed by a presser ring 53. The support body 50 and the mounting plate 51 are sealed by face seals at the faces of the support body 50 and the mounting plate 51. The mounting plate 51 and a flange 52a of the terminal box 52 are sealed to each other by an O-ring. The flange 52a of the terminal box 52 made of nickel, aluminum, stainless steel, or the like is hermetically fixed on a bottom wall 36a of the evacuating chamber 36 by means of a fixing means, not shown.

The support member 50 may be formed of a material excellent in corrosive gas resistance and plasma resistance, e.g., a ceramic material such as Al₂O₃, AlN, SiC and graphite. Herein, nitride aluminum is used.

Disposed in the substantially cylindrical support member 50 are the feed line 17a, the feed line 17b, and a feed line 57 for thermocouple that feeds power to the thermocouple (TC) 16b. The feed lines 17a and 17b are insulatingly covered with sheathes 54 made of an insulating material (e.g., ceramics such as Al₂O₃). Upper portions of the feed lines 17a and 17b pass through an insulating plate 55 to be inserted into the susceptor 12. The feed lines 17a, 17b and the feed line 57 for thermocouple are supported so as not to come in contact with each other.

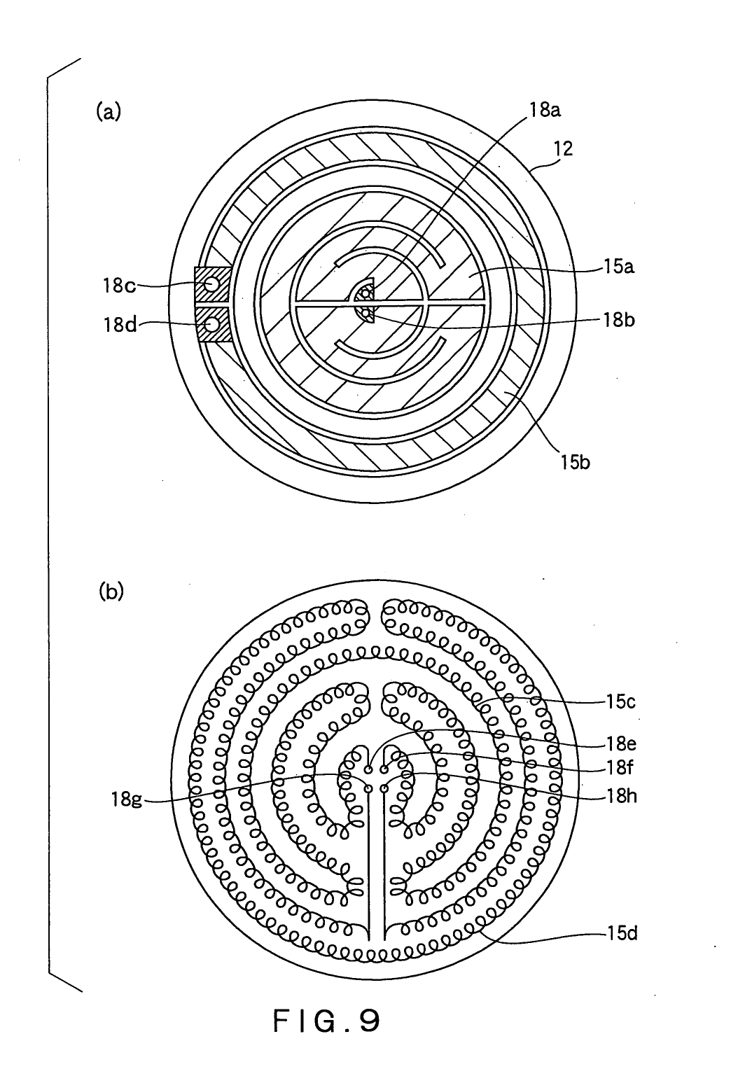

FIG. 9(a) is a horizontal cross sectional view showing an arrangement example of the heaters 15a and 15b embedded in the susceptor 12. Ends of the feed line 17a are connected to the inside heater 15a at connecting parts 18a and 18b. The feed line 17b is laterally bent in the susceptor 12, and ends of the feed line 17b are connected to the outside heater 15b at connecting parts 18c and 18d. An upper end of the feed line 57 for thermocouple is inserted into the susceptor 12.

Coil heaters 15c and 15d as shown in FIG. 9(b) may be used as heaters embedded in the susceptor 12. The inside coil heater 15c and the outside coil heater 15d are arranged such that the inside coil heater 15c is connected to ends of the feed line 17a at connecting parts 18e and 18f, and that the outside coil heater 15d is connected to ends of the feed line 17b at connecting parts 18g and 18h.

Lower ends of the feed lines 17a and 17b and the feed line 57 for thermocouple pass through the mounting plate 51 and the wall of the terminal box 52 to be inserted into the terminal box 52. In the terminal box 52, the feed lines 17a and 17b are connected to connecting terminals 58a and 58b from the heater power source 16a. In FIG. 8, the reference number 56a is an attachment, which is made of an insulating material (e.g., a ceramics such as Al₂O₃), for fixing the connecting terminals 58a and 58b. Similarly, the reference number 56b is an attachment, which is made of an insulating material (e.g., a ceramics such as Al₂O₃), for fixing the feed lines 17a and 17b.

Next, a film forming operation of the film forming apparatus 100 is described below.

At first, TiCl₄ gas and a reduction gas such as NH₃ gas are introduced into the chamber 11 in which no wafer W is contained, so that the surface of the susceptor 12 is subjected to a precoating-film forming process.

After the precoating process is finished, the introduction of the TiCl₄ gas and the reduction gas is stopped, and the inside of the chamber 11 is rapidly evacuated by the evacuating device 38 to create a vacuum therein. Then, the gate valve 43 is opened, a wafer W is loaded into the chamber 11 by a wafer conveyor through the loading/unloading port 42, and the wafer W is placed on the susceptor 12. Then, the wafer W is preheated while N₂ gas is supplied into the chamber 11. At a time when a temperature of the wafer W becomes nearly stable, N₂ gas, NH₃ gas or H₂ gas as a reduction gas, and TiCl₄ gas are introduced at predetermined flow rates. At this time, the gases are pre-flown through the evacuating line, and thereafter the gases are introduced into the chamber 11 through the showerhead 20 at the predetermined flow rates, the wafer W is heated such that an in-plane temperature of the wafer W is made uniform, by independently supplying power to the heaters 15a and 15b at a predetermined power ratio from the heater power source 16a, while maintaining pressure in the chamber 11 at a predetermined value. Thus, a TiN film is formed on the wafer W. The temperature for heating the substrate at this time is in a range of 400 to 700° C., preferably about 600° C. When a Ti film is formed, the gases may be converted into plasma by supplying a radiofrequency power from the radiofrequency power source 34. In a case where plasma is generated, since the reactivity of the gases is high, the temperature of the wafer W is preferably in a range of 300 to 700° C., more preferably about 400 to 600° C.

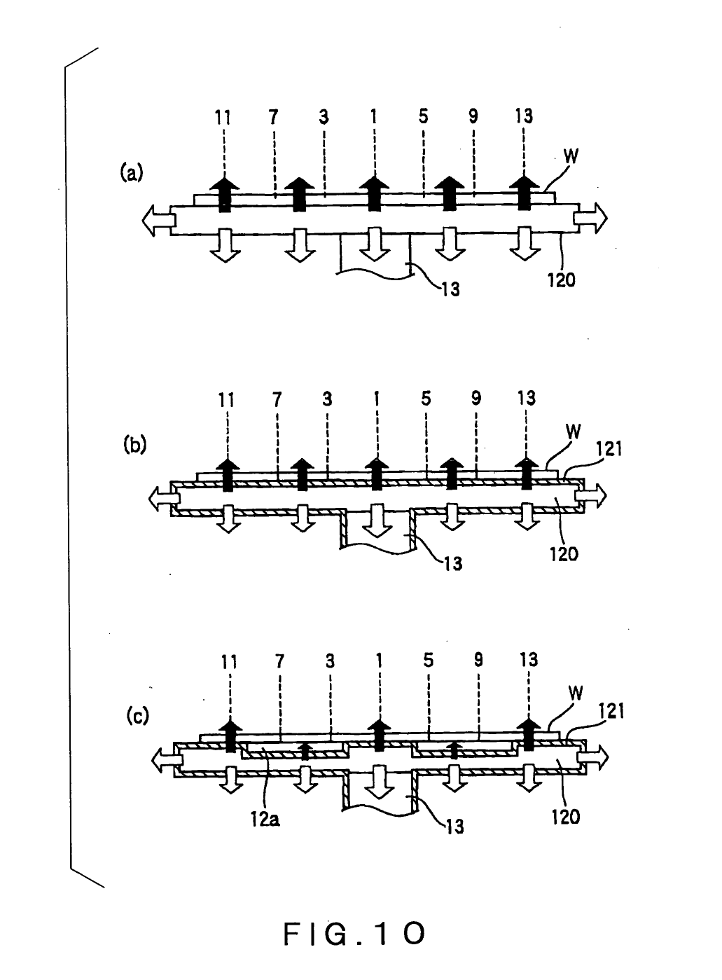

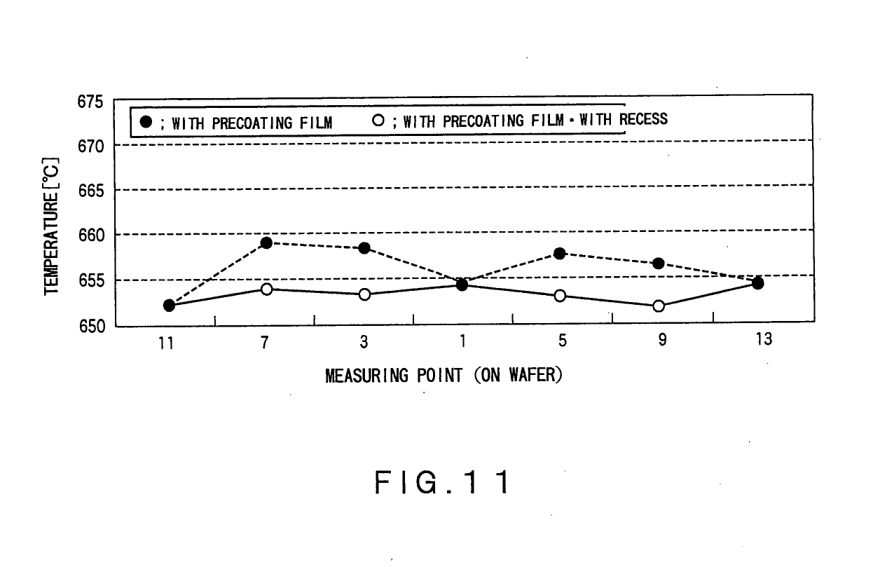

Next, results of experiments for confirming the effect of the present invention is described below with reference to FIGS. 10 and 11. FIG. 10(a) shows a conventional susceptor 120 on which a precoating film is not yet formed. FIG. 10(b) shows the conventional susceptor 120 on which a precoating film has been formed. FIG. 10(c) shows the susceptor 12, provided with the recess 12a, on which a precoating film has been formed. The numbers 1, 3, 5, 7, 9, 11, and 13 in these drawings mean measuring points at which the temperature on a wafer W is measured by using the wafer with a thermocouple (TC), and the numbers correspond to the respective measuring points in FIG. 11. The point 1 corresponds to a center portion of the wafer W, and the points 11 and 13 correspond to peripheral portions of the wafer W. White arrows in FIGS. 10(a) to 10(c) indicate an amount of heat released from the susceptor 12, and black arrows indicate an amount of heat transferred from the susceptor 12 to the wafer W.

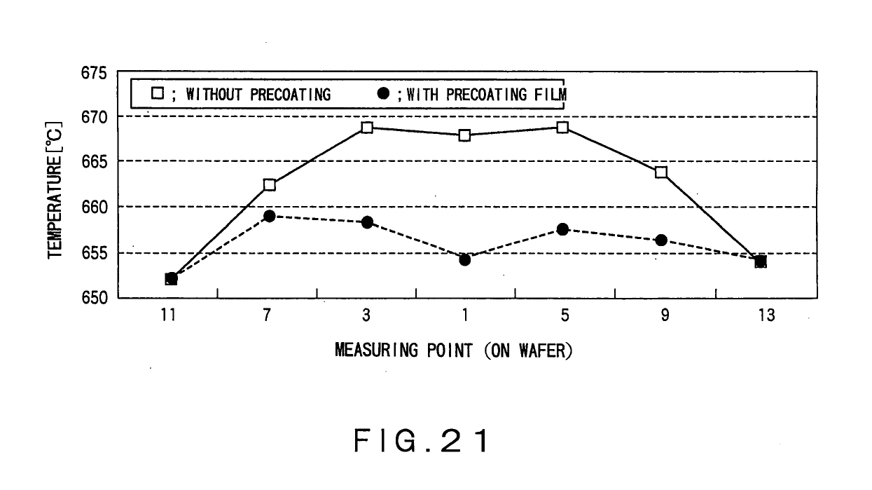

As shown in FIG. 10(a), temperature control was performed to the susceptor 120, on which no precoating film was formed, at a power ratio for forming a precoating film. As can be shown by the data plotted with a square in FIG. 21, the temperature distribution of the wafer W was that a temperature of the wafer W is low at the peripheral portion (measuring points 11 and 13) and high at the center portion (measuring points 1, 3, and 5). A temperature difference between the center portion and the peripheral portion of the wafer W (difference between the highest temperature and the lowest temperature) was about 15° C. The reason therefor is as follows.

When the center portion and the peripheral portion of the susceptor 120 is compared to each other, since surface area per unit volume of the peripheral portion is larger than that of the central portion, temperature non-uniformity is invited. In addition, in an actual film forming apparatus, the wafer W undergoes thermal reflection from the showerhead 20 facing the susceptor 120. The solid angle of the thermal reflection from the showerhead 20 facing the wafer W to the wafer W is larger at the center portion and smaller at the peripheral portion. Thus, the center portion of the wafer W undergoes a larger thermal reflection so that the temperature thereof is relatively raised. On the other hand, the peripheral portion undergoes a smaller thermal reflection so that a temperature thereof is relatively lowered. These factors deteriorate thermal uniformity of the susceptor (in-plane temperature uniformity of the wafer W).

FIG. 10(b) shows the susceptor 120, whose wafer support surface is flat, which has been subjected to a precoating process to form thereon a precoating film 121. In this case, since thermal radiation from the surface of the susceptor 120 and thermal reflection from the showerhead 20 were generally decreased, an in-plane temperature of the wafer W was lowered as a whole. However, as compared with the intermediate area of the wafer W (measuring points 3 and 7, and measuring points 5 and 9) between the center portion (measuring point 1) and the peripheral portion (measuring points 11 and 13), the temperature of the center portion of the wafer W was considerably lowered. Thus, the in-plane temperature distribution had two peaks in a radial direction in which the temperatures of the center portion and the peripheral portion of the wafer W are low, while the temperature of the intermediate area therebetween is high. Namely, even though the power ratio is controlled for uniformizing the in-plane temperature of the wafer W, non-uniform temperature distribution appears as shown in the data plotted by a black circle in FIG. 11. This is because, since the precoating film 121 was not formed at a part connected to the support member 13, a larger amount of heat was drawn from the susceptor 120 to the support member 13 through this part. That is, drawing of heat by the support member 13 (heat transfer through the support member 13 and thermal radiation into the inside space of the support member 13) caused lowering of temperature at the center portion of the susceptor 120, which was reflected on the in-plane temperature distribution of the wafer W. Influence of the drawing of heat by the support member on the in-plane temperature distribution of the wafer W is not so conspicuous under the condition [FIG. 10(a)] where a precoating film is not formed, since the thermal radiation from the susceptor 120 and the thermal reflection from the showerhead 20 are large. However, under the condition [FIG. 10(b)] where the precoating film is formed on the susceptor 120, since the thermal radiation and the thermal reflection are generally suppressed, but the heat transfer to the support member 13 and the thermal radiation into the support member 13 are still large, the influence become conspicuous.

In the susceptor 12 in one embodiment of the present invention, as shown in FIG. 10(c), a groove, i.e., the recess 12a was annularly formed to correspond to the intermediate area (measuring points 3 and 7, and the measuring points 5 and 9) between the center portion and the peripheral portion of the wafer W. Since the recess 12a provided a gap between the wafer support surface of the susceptor 12 and the wafer W, heat transfer to the intermediate area of the wafer W was suppressed. That is, as compared with other areas, heat transfer from the susceptor 12 to the wafer W is reduced at the part where the recess 12a is formed.

Thus, as shown by white circles in FIG. 11, even when the precoating film was formed, the temperature of the intermediate area of the wafer W could be lowered to the same degree as those of the center portion and the peripheral portion of the wafer W. As described above, by controlling the shape and the depth of the recess and the chamber internal pressure, it is possible to achieve in-plane temperature uniformity of the wafer W with high accuracy.

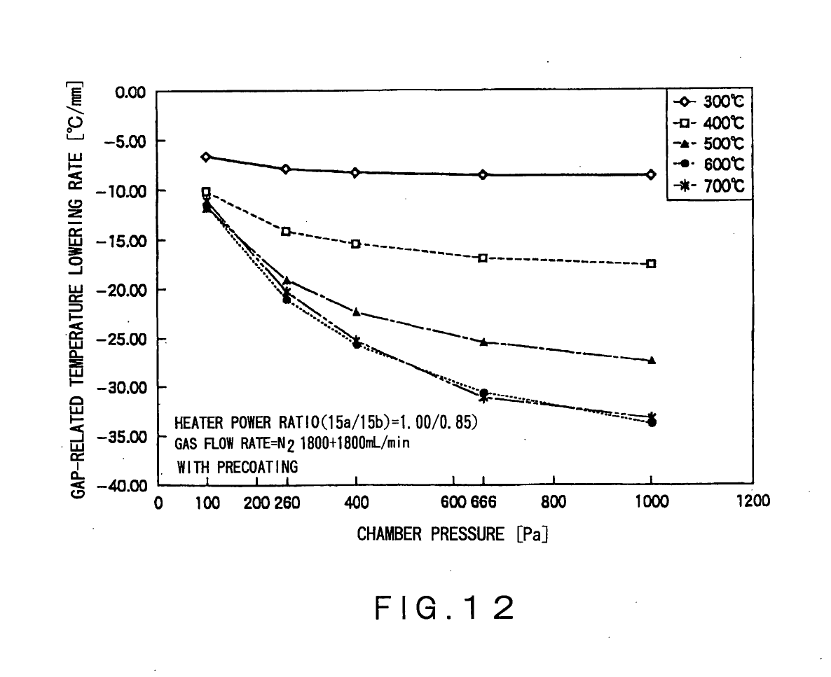

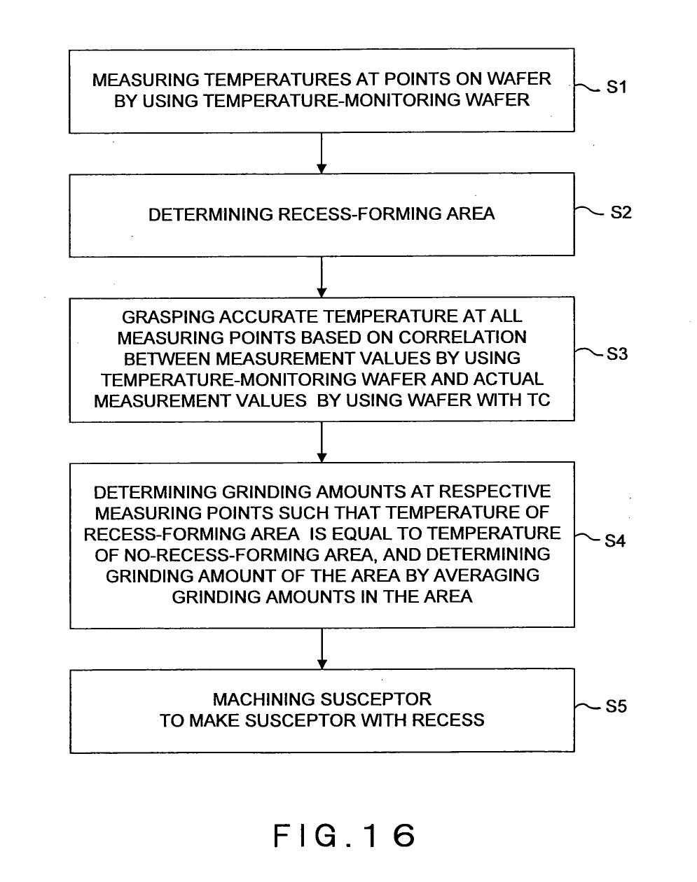

Next, other embodiments of the present invention are described below with reference to FIGS. 12 to 20.

The effect produced by the formation of the recess for reducing an amount of heat transferred from the susceptor 12 to a wafer W depend on factors such as the depth of the recess (i.e., the distance from the bottom of the recess to the rear surface of the wafer W; or the gap), the chamber internal pressure, the set temperature of the heaters 15a and 15b in the susceptor 12, and the existence of precoating. Thus, an experiment was conducted under the below-described conditions by using a film forming apparatus 100 having the same structure as the apparatus shown in FIG. 1, so as to examine how the temperature lowering rate in relation to the gap is affected by the existence of precoating, the chamber internal pressure, and the set temperature of the susceptor 12. The “temperature lowering rate” represents the degree of the temperature lowering at a certain measuring point on a wafer W when a recess is formed in the susceptor, as compared with the temperature at the same measuring point when the susceptor is not provided with a recess; and the “temperature lowering rate” is expressed as the change in the temperature per 1 mm of the depth (gap) of the recess. The temperature lowering rate was calculated as follows.

At first a wafer with TC was placed on the susceptor 12. Then, the temperature was measured while gradually elevating the wafer with the TC by the wafer support pins 39 so as to vary the distance between the wafer and the surface of the susceptor 12. Then, temperature lowering rate was calculated based on the temperature lowering which occurs when the wafer with the TC is thoroughly separated from the susceptor 12 by using the following expression:

Lowering of Temperature[° C.]/Distance(mm)between Wafer with TC and Susceptor=Temperature Lowering Rate [° C./mm].

### <Experiment Condition>

Gas Flow Rate (Gas Inlet Port 21); N₂ 1800 mL/min (sccm)
Gas Flow Rate (Gas Inlet Port 22); N₂ 1800 mL/min (sccm)
Heater Power Ratio (Heater 15a/Heater 15b)=1.00/0.85

### Chamber Internal Pressure; 100 Pa, 260 Pa, 400 Pa, 666 Pa, 1 kPa Heater Set Temperature; 300° C., 400° C., 500° C., 600° C., 650° C., 680° C., 700° C.

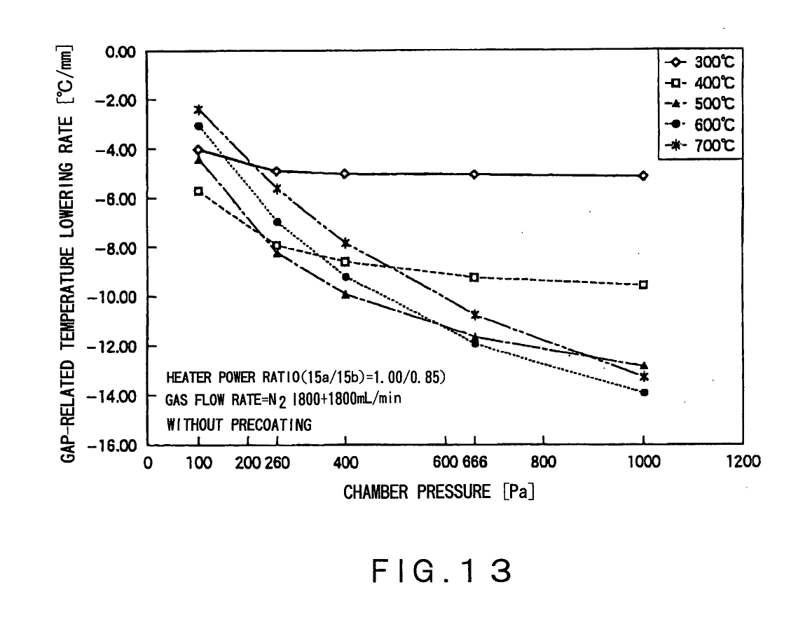

FIGS. 12 and 13 are graphs showing the relationship between the gap-related temperature-lowering rate and the chamber internal pressure, FIG. 12 showing a case with precoating, and FIG. 13 showing a case without precoating. As can be seen from FIGS. 12 and 13, regardless of existence of precoating, as the internal pressure was raised, the absolute value of the gap-related temperature-lowering rate [° C./mm] increased. In general, there was a tendency that, the higher the set temperature of the suscepter 12 was, the more the gap-related temperature-lowering rate depended on the pressure. Namely, the higher the pressure was, the more the absolute value of the temperature lowering rate increased.

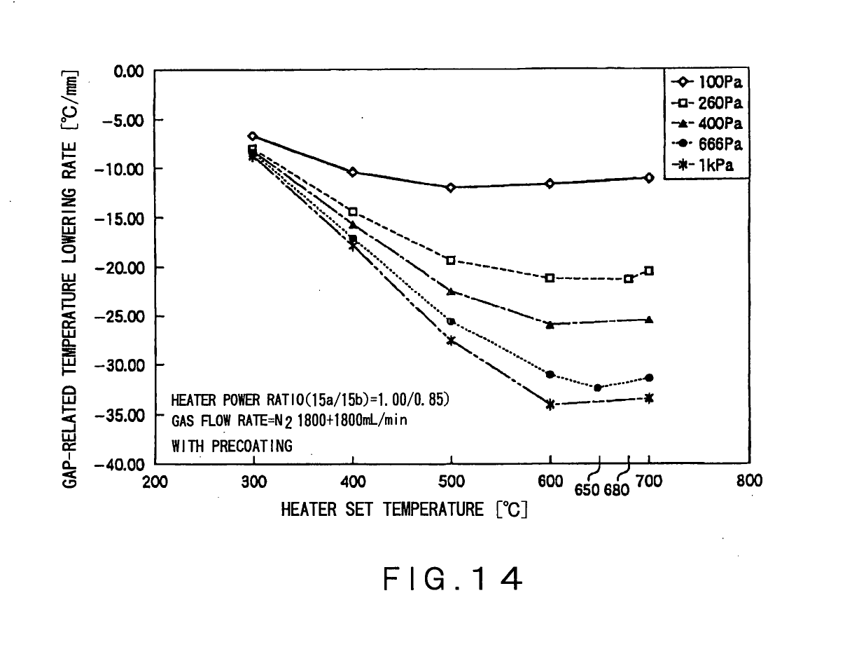

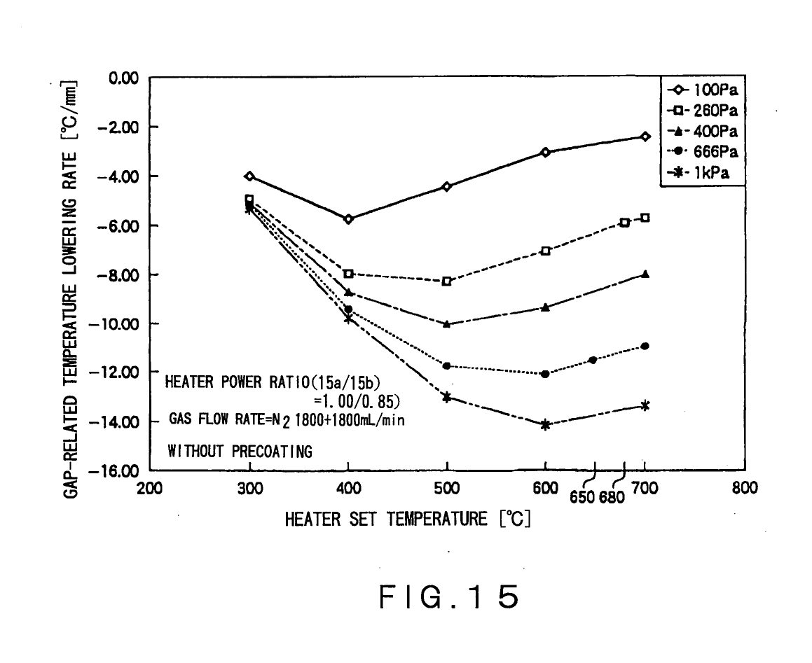

FIGS. 14 and 15 are graphs showing the relationship between the gap-related temperature-lowering rate [° C./mm] and the set temperature of the susceptor 12, FIG. 14 showing a case with precoating, and FIG. 15 showing a case without precoating. As can be seen from FIG. 14 showing the case with precoating, the absolute value of the gap-related temperature-lowering rate [° C./mm] increased, when the set temperature of the susceptor 12 was up to about 500° C. to 600° C. However, at the higher temperature, increase in the absolute value of the temperature lowering rate [° C./mm] plateaued. As can be seen from FIG. 15 showing the case without precoating, when the set temperature of the susceptor 12 exceeded in a range of 400° C. to 600° C., increase in the absolute value of the temperature lowering rate [° C./mm] plateaued. As shown in FIGS. 14 and 15, it can be understood that the lower the process pressure was, the sooner the absolute value of the gap-related temperature-lowering rate [° C./mm] plateaued.

Based on the result of the basic experiments, the shape of a recess to be formed in the susceptor 12 was determined according to the following steps.

In the following steps, the wafer temperature was measured by direct measurement with the use of a wafer with TC (thermocouple), and by indirect measurement with the use of a wafer for monitoring temperature. The wafer for monitoring temperature is a semiconductor wafer manufactured by implanting ionized impurities into the wafer (see, JP2000-208524A and JP2004-335621A). By measuring sheet resistance of the wafer, the wafer temperature can be indirectly measured.

By using the wafer for monitoring temperature, temperature measurement is conducted at a plurality of (e.g., 5 to 17) points on the wafer W (step S1). As heating conditions, there were a condition in which the susceptor set temperature was 680° C. and the chamber internal pressure was 260 Pa (Condition 1), and a condition in which the susceptor set temperature was 650° C. and the chamber internal pressure was 666 Pa (Condition 2).

Then, an area in which a recess was to be formed was determined (step S2). At this time, with a view to preventing generation of depositions on the back surface of the wafer W, the peripheral portion of the susceptor 12 was not ground. Specifically, the peripheral portion of the susceptor 12 remained without being ground, thereby forming the wafer support surface (second support surface S_{E}) extending inwardly from the outer peripheral edge of the wafer W over a width in a range of 1 to 30 mm, for example. In addition, in order to prevent that the recess can not function sufficiently if the wafer W is warped when the temperature became high, the center portion of the susceptor 12 was not ground to form the first support surface (S_{C}). In this case, the non-ground area in the susceptor center portion (center projection) had a diameter which was equal to or slightly larger than the diameter of the support member 13 supporting the susceptor 12.

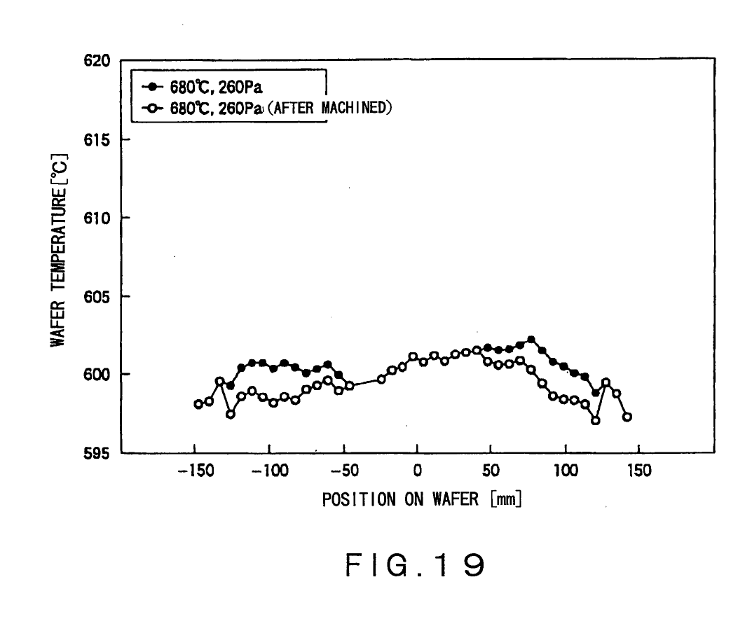

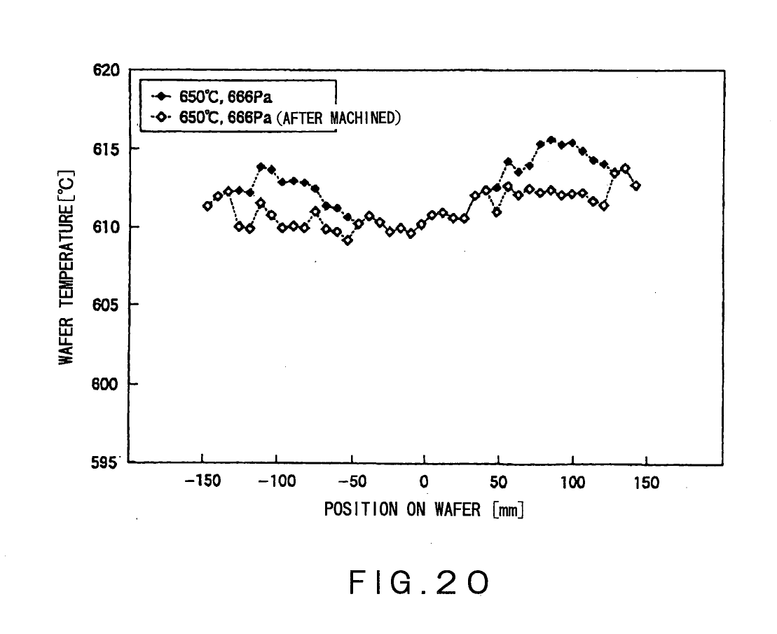

Then, the correlation between the value measured with the use of the wafer for monitoring temperature and the value actually measured by the wafer with the TC was obtained with respect to suitable measuring points, and the correction value thereof was determined. The correction value was applied to all the measuring points so that the accurate temperature at every measuring point was grasped (step S3). The data of the temperature measured by the wafer with TC were plotted with black symbols (black circles or black diamonds) in FIGS. 19 and 20. In FIGS. 19 and 20, the axis of abscissa indicates radial positions on the wafer, and 0 (zero) means the wafer center.

Then, referring to the basic experiment data of the temperature lowering rate shown in FIGS. 12 to 15, the grinding amount at each measuring point was determined such that the temperature of the part to be ground (recess-forming area) was equal to the temperature of the area where a recess was not formed (step S4). The grinding amount can be calculated based on the following equation:

Grinding Amount(mm)=Temperature Difference/Temperature Lowering Rate

Here, the “temperature difference” means the difference between the temperature of the area in which a recess is to be formed, and the temperature of the area in which a recess is not formed. Then, the required grinding amounts were averaged circumferentially (positions on respective concentric circles on the susceptor 12) to obtain the grinding amount.

After the area in which a recess is formed and the grinding amount thereof were determined as described above, the susceptor 12 was machined, so that the susceptor 12 provided with the recess was manufactured (step S5).

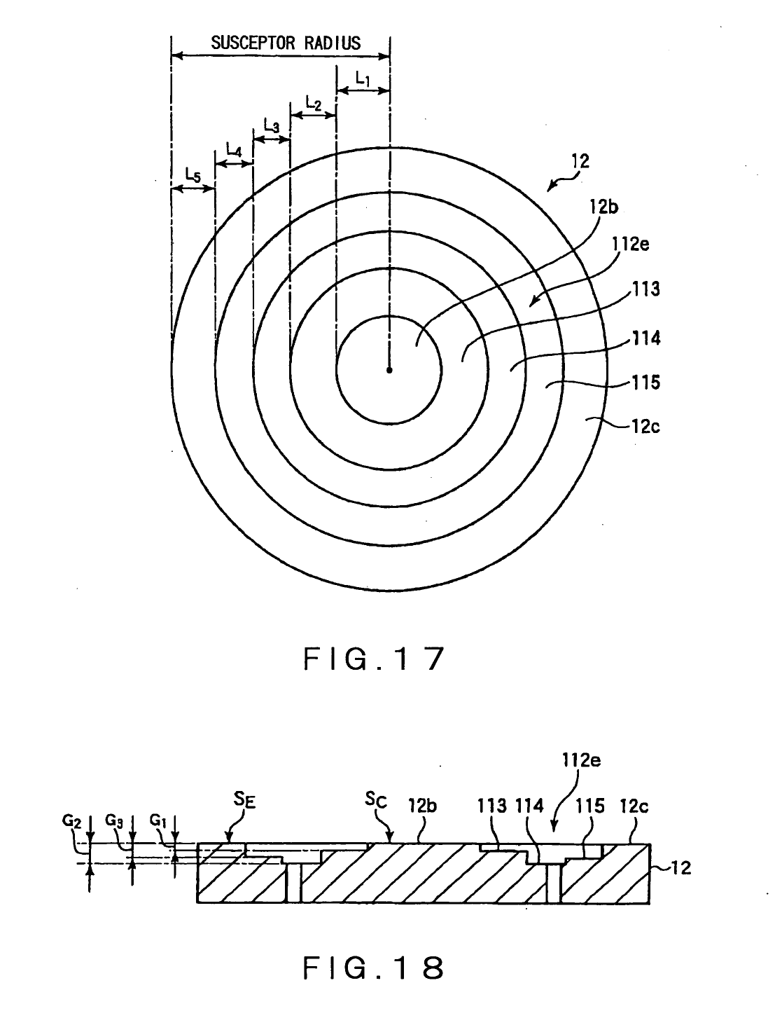

The structure of the susceptor 12 manufactured according to the steps S1 to S5 is shown in FIGS. 17 and 18. The susceptor 12 had the recess 112e in which the first bottom portion 113, the second bottom portion 114, and the third bottom portion 115 were formed in that order from the center side to the peripheral side of the susceptor 12. The radius Lᵢ of the center projection 12b was 45 mm. In the recess 112e, the radial width L₂ of the first bottom portion 113 was 30 mm, the radial width L₃ of the second bottom portion 114 was 25 mm, and the radial width L₄ of the third bottom portion 115 was 25 mm. The radial width L₅ of the peripheral projection 12c was 25 mm.

In the recess 112e, the gap G₁ of the first bottom portion 113 was 0.05 mm, the gap G₂ of the second bottom portion 114 was 0.13 mm, and the gap G₃ of the third bottom portion 115 was 0.1 mm.

Temperature measurement was conducted under Conditions 1 and 2 by using the susceptor 12 provided with the thus formed recess 112e to heat wafers with TCs. The result is plotted in FIGS. 19 and 20 with white symbols (white circles or white diamonds). As compared with the plot with black symbols (without recess) and the white symbols (with recess) in FIGS. 19 and 20, it can be understood that, from the plot with the white symbols, the temperature at a position (intermediate area) between the center portion and the peripheral portion of the wafer W was lowered so that the in-plane temperature distribution became uniform. Thus, it was confirmed that, due to the formation of the recess 112e, the temperature difference in the wafer plane can be reduced.

Not limited to the foregoing embodiments, the present invention is not limited to the foregoing embodiments, and various modifications are possible. For example, in the foregoing embodiments, the present invention is applied to the formation of a TiN film or a Ti film and the formation of a W film. However, not limited to these films, the present invention can be applied to formation of another CVD film. Further, not limited to formation of a film, another process is possible as long as the process include heating step. The present invention may also be applied to an apparatus that performs only a heating treatment. Furthermore, although a semiconductor wafer is taken as an example of a substrate, the present invention is not limited thereto and may be applied to another substrate such as a glass substrate for a liquid crystal display (LCD). In this case, a large substrate mount table equipped with the larger number of heaters should be used in accordance with a larger substrate. Therefore, the advantage, which can be obtained by the formation of a recess to adjust the temperature so as to achieve in-plane uniformity of the wafer temperature distribution, can be more noticeably enjoyed.

1. A substrate processing apparatus that performs a heat treatment to a substrate, or performs a treatment while heating a substrate, said apparatus comprising:
a chamber;
an evacuating means that decreases pressure in the chamber;
a substrate mount table that supports the substrate in the chamber; and
a heater embedded in the substrate mount table to heat the substrate mount table thereby to heat the substrate supported on the substrate mount table,
wherein the substrate mount table has a first support surface formed in a center portion of the substrate mount table to support the substrate, a second support surface formed in a peripheral portion of the substrate mount table to support the substrate, and a recess formed between the first support surface and the second support surface, so that a gap is formed between the substrate placed on the substrate mount table and a bottom surface of the recess.

2. The substrate processing apparatus according to claim 1, wherein a size of the gap varies with location.

3. The substrate processing apparatus according to claim 2, wherein the bottom surface of the recess has a step.

4. The substrate processing apparatus according to claim 3, wherein the bottom surface of the recess has a plurality of annular areas which are arranged concentrically, and adjacent annular areas have different heights.

5. The substrate processing apparatus according to claim 1, wherein the substrate mount table is supported by a support member connected to a center portion of the substrate mount table.

6. The substrate processing apparatus according to claim 5, wherein a region where the first support surface is provided substantially corresponds to a region where the support member is provided.

7. (canceled)

8. (canceled)

9. The substrate processing apparatus according to claim 1, wherein the heating means heater includes a first heater element disposed in a center portion of the substrate mount table and a second heater element disposed to surround the first heater element.

10. A substrate mount table for supporting a substrate wherein:
a heater is embedded in said substrate mount table to heat said substrate mount table thereby to heat a substrate supported on said substrate mount table; and
said substrate mount table has a first support surface formed in a center portion of the substrate mount table to support the substrate, a second support surface formed in a peripheral portion of the substrate mount table to support the substrate, and a recess formed between the first support surface and the second support surface, so that a gap is formed between the substrate placed on the substrate mount table and a bottom surface of the recess.

11. The substrate mount table according to claim 10, wherein a size of the gap varies with location.

12. The substrate mount table according to claim 11, wherein the bottom surface of the recess has a step.

13. The substrate mount table according to claim 12, wherein the bottom surface of the recess has a plurality of annular areas which are arranged concentrically, and adjacent annular areas have different heights.

14. The substrate mount table according to claim 10, wherein the substrate mount table is supported by a support member connected to a center portion of the substrate support table.

15. The substrate mount table according to claim 14, wherein a region where the first support surface is provided substantially corresponds to a region where the support member is provided.

16. (canceled)

17. (canceled)

18. The substrate mount table according to claim 10, wherein the heater includes a first heater element disposed in a center portion of the substrate mount table and a second heater element disposed to surround the first heater element.

19. The substrate processing apparatus according to claim 1, wherein the substrate mount table is made of a ceramic material.

20. The substrate mount table according to claim 11, wherein said substrate mount table is made of a ceramic material.
